(19) United States
(12) Patent Application Publication
(10) Pub. No.: US 2024/0012572 A1
(43) Pub. Date: Jan. 11, 2024

(54) OPERATIONALIZATION OF MEMORIES USING MEMORY INFORMATION SETS

(71) Applicant: Hewlett-Packard Development Company, L.P., Spring, TX (US)

(72) Inventors: Kang-Ning Feng, Taipei City (TW); Reily CHANG, Taipei City (TW); Wei-Chih HUANG, Taipei City (TW)

(73) Assignee: Hewlett-Packard Development Company, L.P., Spring, TX (US)

(21) Appl. No.: 18/004,442

(22) PCT Filed: Jul. 14, 2020
(86) PCT No.: PCT/US2020/042025

§ 371 Date: Jan. 5, 2023

(51) Int. Cl. G06F 3/06

(52) U.S. Cl. CPC G06F 3/0632; G06F 3/0604; G06F 3/0683

(57) ABSTRACT

Examples for operationalization of memories using memory information sets are described. In an example, a memory information set corresponding to a first memory in a computing device may be selected from amongst a plurality of memory information sets. The selected memory information set may be loaded into a second memory of the computing device, for operationalizing the first memory. The second memory may also store instructions usable for starting the computing device.

### BACKGROUND

A computing device includes a memory, for example, for storing instructions and data to be accessed by a processor of the computing device. Upon being powered on, the computing device may have to perform various actions to bring the memory to an operational state. The actions may include, for example, determining the type of the memory and initializing, testing, and calibrating the memory. The actions may be performed by utilizing an information set corresponding to the memory.

### BRIEF DESCRIPTION OF DRAWINGS

The detailed description is provided with reference to the accompanying figures. In the figures, the left-most digit(s) of a reference number identifies the figure in which the reference number first appears. The same numbers are used throughout the drawings to reference like features and components.

FIG. 1 illustrates a computing device in which a first memory is operationalized using a memory information set, according to an example implementation of the present subject matter;

FIG. 2 illustrates a computing device in which a memory information set is selected for operationalizing a first memory, according to an example implementation of the present subject matter;

FIG. 3(a) illustrates a method for operationalization of a first random access memory (RAM), according to an example implementation of the present subject matter;

FIG. 3(b) illustrates a method for operationalization of a first RAM, according to an example implementation of the present subject matter;

FIG. 4 illustrates a computer-implemented method for operationalizing a first memory using a memory information set, according to an example implementation of the present subject matter; and

FIG. 5 illustrates a computing environment implementing a non-transitory computer-readable medium for operationalizing a volatile memory of a computing device using a memory information set, according to an example implementation of the present subject matter.

### DETAILED DESCRIPTION

A computing device may include multiple memories. For example, a first memory may be used for storing instructions to be accessed and executed by a processor of the computing device. The first memory may be, for example, a volatile memory, such as a random access memory (RAM). Upon being powered on, the computing device may have to perform various actions to bring the first memory to an operational state. The performance of the actions to bring the first memory to the operational state may be referred to as operationalization of the first memory. To operationalize the first memory, the computing device may utilize information, referred to as a memory information set, related to the first memory. The information in the memory information set may include, for example, a model of the first memory and timings to be used to access the first memory.

In some cases, the memory information set may be stored in a second memory that is used to store instructions usable for starting up the computing device. The second memory may be a non-volatile memory and the instructions usable for starting up the computing device may be Basic Input/Output System (BIOS), Unified Extensible Firmware Interface (UEFI), or both. The instructions usable for starting up the computing device may be referred to as start-up instructions. The information and instructions stored in the second memory may be collectively referred to as initialization components, as the information and the instructions may be utilized for or during initialization (i.e., powering up) of the computing device.

Sometimes, the initialization components in the second memory may have to be updated. The updating may be achieved by loading contents of an update package having updated initialization components into the second memory. The update package may include a memory information set that corresponds to the first memory and that is to replace the memory information set previously stored in the second memory. In some cases, the update package may include a plurality of memory information sets corresponding to different memories, such as different models of memory. The provision of the plurality of memory information sets in the update package makes the update package common for a plurality of computing devices, each having a different memory. Thus, the update package may be distributed to several computing devices for updating the initialization components. However, since the update package has multiple memory information sets, the loading of the contents of the update package into the second memory for performing the update causes the multiple memory information sets to be loaded into the second memory. The loading of multiple memory information sets into the second memory reduces the space available in the second memory for storing the start-up instructions.

In accordance with the present subject matter, an update package may include initialization components having start-up instructions for starting up the computing device. In an example, the initialization components may also include a common memory information set, which may include information common to a plurality of memories. For instance, the common memory information set may include information usable for a basic level of operationalization of multiple memories. The update package may also include a memory information block having a plurality of memory information sets. Each memory information set in the memory information block may correspond to a different memory.

In operation, the initialization components may be loaded into the second memory for updating contents of the second memory. The loading of the initialization components into the second memory may involve loading the common memory information set. Further, a memory information set corresponding to the first memory may be selected from amongst the memory information sets in the memory information block. The selected memory information set may then be loaded into the second memory and be used to operationalize the first memory. The loading of the selected memory information set into the second memory may involve replacing the common memory information set with the selected memory information set.

In an example, prior to loading the initialization components into the second memory, a previous memory information set that was previously stored in the second memory for operationalizing the first memory may be backed-up in a third memory of the computing device. Further, the common memory information set may also be backed-up in the third memory. If an attempt to operationalize the first memory using the selected memory information set fails, the common memory information set or the previous memory information set may be fetched from the third memory and used for operationalizing the first memory.

The provision of a memory information block in the update package and the selection of a memory information set corresponding to the memory in a computing device from the memory information block helps to avoid storing the plurality of memory information sets in the memory that is to store start-up instructions (i.e., the second memory). Therefore, adequate space may be made available in the second memory for storing the start-up instructions. Further, since not all memory information sets in the memory information block are to be stored in the second memory, the memory information block may have several memory information sets corresponding to several memories, without having regard to the space available in the second memory. Thus, the update package may be utilized to update memory information sets corresponding to several different types of memories. Further, the models or types of memories that can be supported by computing devices may be increased, thereby providing greater flexibility in terms of the model of memory that can be installed in a computing device.

The present subject matter also prevents the use of a dedicated memory to store memory information sets, thereby achieving cost and space savings. The present subject matter can be utilized in scenarios where motherboards are to be made compact. For instance, the present subject matter can be utilized in motherboards implementing a memory down technique, according to which memories are directly soldered onto the motherboard, without utilizing slots and connectors, for space saving.

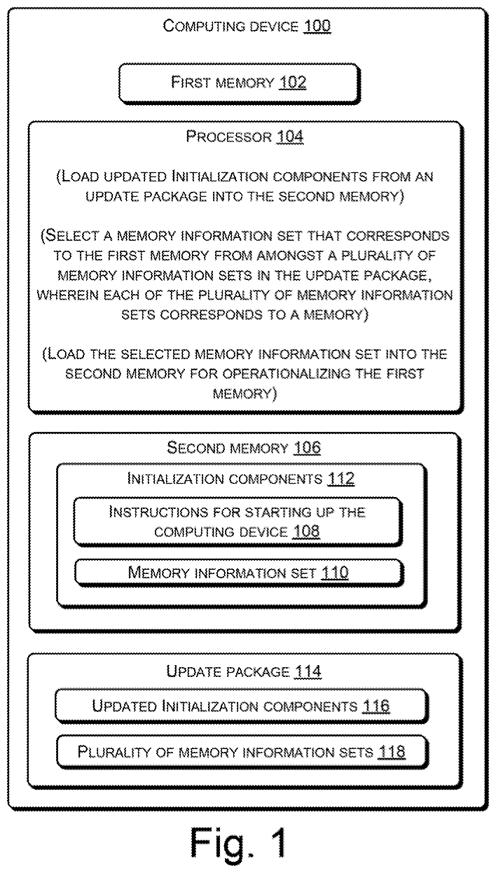

The present subject matter is further described with reference to FIGS. 1-5. It should be noted that the description and figures merely illustrate principles of the present subject matter. Various arrangements may be devised that, although not explicitly described or shown herein, encompass the principles of the present subject matter. Moreover, all statements herein reciting principles, aspects, and examples of the present subject matter, as well as specific examples thereof, are intended to encompass equivalents thereof.

FIG. 1 illustrates a computing device 100 in which a first memory 102 is operationalized using a memory information set, according to an example implementation of the present subject matter. The computing device 100 may be a desktop computer, a laptop computer, a server, or the like. The first memory 102 may be a non-transitory computer-readable medium that can store information. The information may include computer-readable instructions that can be fetched and executed by a processor 104 of the computing device 100. In an example, the first memory 102 may be a volatile memory, such as a random access memory (RAM). The processor 104 may be implemented as a microprocessor, a microcomputer, a microcontroller, a digital signal processor, a central processing unit (CPU), a state machine, a logic circuitry, and/or any device that can manipulate signals based on operational instructions.

The computing device 100 may also include a second memory 106 that is used to store instructions 108 usable for starting up the computing device 100, also referred to as start-up instructions. The second memory 106 may be, for example, a non-volatile memory, such as flash memory and electrically erasable programmable read-only memory (EEPROM). Further, the start-up instructions 108 may include firmware, such as Basic Input/Output System (BIOS) or Unified Extensible Firmware Interface (UEFI), which cause hardware initialization during a booting process and provision of runtime services for operating system (OS) of the computing device 100. In an example, the start-up instructions 108 may include both BIOS and UEFI. In an example, during the booting process, the start-up instructions 108 may be loaded from the second memory 106 into the first memory 102 for the hardware initialization and the provision of runtime services.

The second memory 106 may also store a memory information set 110, which may be used to bring the first memory 102 to an operational state. The memory information set 110 may specify, for example, a model of the first memory 102 and timings to be used to access the first memory 102. The utilization of the memory information set 110 to bring the first memory 102 to an operational state may be referred to as operationalization or training of the first memory 102. The operationalization may be performed when the computing device 100 is powered up.

The information and the instructions stored in the second memory 106 may be collectively referred to as initialization components 112, as the information and the instructions may be utilized for or during initialization (i.e., powering up) of the computing device 100. In an example, an update package 114 may be used to update contents of the second memory 106. The update package 114 may be, for example, a file having components provided as part of an update release by a manufacturer of the computing device 100. For instance, the update package 114 may include updated initialization components 116 to be loaded into the second memory 106. The updated initialization components 116 may include, for example, updated start-up instructions. The loading of the updated initialization components 116 may involve replacement of the initialization components 112, which previously exists in the second memory 106, with the updated initialization components 116. In an example, the update package 114 may be stored on a storage (not shown in FIG. 1) of the computing device 100.

The update package 114 may also include a plurality of memory information sets 118. The plurality of memory information sets 118 may be provided as part of a memory information block (not shown in FIG. 1). Each memory information set in the memory information block corresponds to a memory, such as a model of memory, and may be used to operationalize the corresponding memory. The computing device 100 may select the memory information set that corresponds to the first memory 102 from amongst the plurality of memory information sets 118. In an example, the memory information set that corresponds to the first memory 102 may be an updated version of the memory information set 110. Similarly, other memory information sets corresponding to other memories may be updated versions of memory information sets corresponding to those memories.

In an example, the selection of the memory information set may be performed, for example, based on a comparison of an identifier associated with each memory information set and an identifier corresponding to the first memory 102. The selected memory information set may be loaded into the second memory 106, so that operationalization of the first memory 102 may be performed using the selected memory information set.

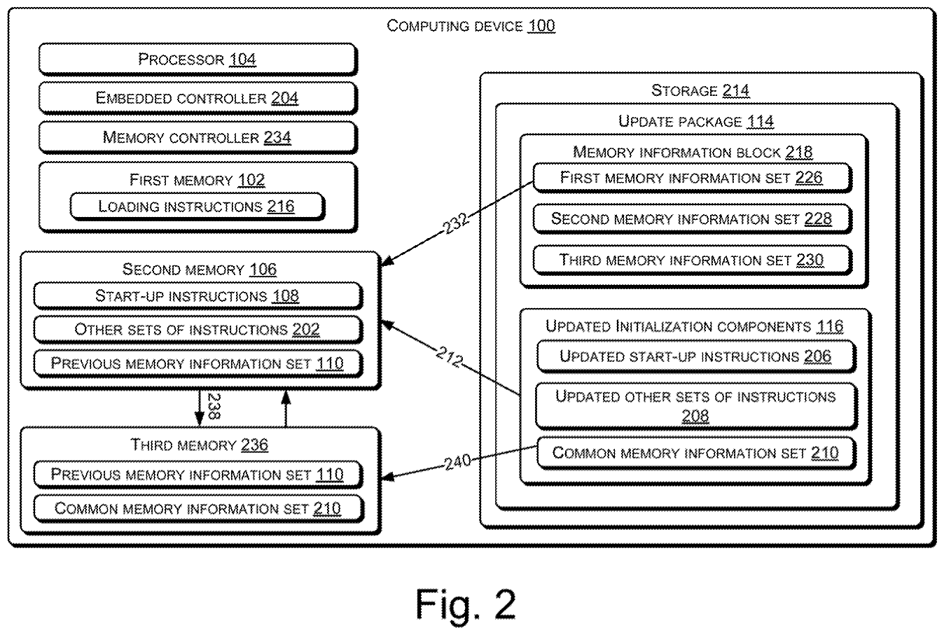

FIG. 2 illustrates the computing device 100 in which a memory information set is selected for operationalizing the first memory 102, according to an example implementation of the present subject matter. Here, the first memory 102 is explained as a RAM and is referred to as a first RAM 102. However, the explanation provided below will be applicable other types of memories that are to be operationalized during initialization of computing devices.

In an example, the operationalization of the first RAM 102 may include performing actions that facilitate the processor 104 to reliably read data from and write data to the first RAM 102. The actions may include, for example, determining latencies that affect read and write speeds of the first RAM 102. The operationalization may be performed with the help of the memory information set 110 corresponding to the first RAM 102. For instance, the memory information set 110 may specify the latencies that affect the read and write speeds of the first RAM 102. In an example, the memory information set 110 may be in accordance with serial presence detect (SPD), which is a standardized manner to allow a computing device to access information about a memory. Accordingly, the memory information set 110 may be referred to as SPD data 110. The memory information set 110 may also be referred to as a previous memory information set 110, as the memory information set 110 is replaced with another memory information set from the update package, as will be explained later.

The memory information set 110 may be stored in the second memory 106 that is to store the start-up instructions 108, which are usable for the starting-up of the computing device 100. If the start-up instructions 108 includes BIOS, the second memory 106 may also be referred to as a BIOS memory. An example technique where a memory information set is stored in the memory storing the start-up instructions is a memory down technique, where memories are directly soldered onto the motherboard and where a dedicated memory for storing SPD data may not be used.

In an example, the start-up instructions 108 may include several sets of instructions, where each set is stored in a separate volume provisioned in the second memory 106. In an example, each volume may have a corresponding filesystem. In addition to the memory information set 110 and the start-up instructions 108, the second memory 106 may include other sets of instructions 202, such as an image having firmware for an embedded controller (EC) 204 of the computing device 100. The information, such as the memory information set 110, and instructions, such as the start-up instructions 108 and other sets of instructions 202, stored on the second memory 106 may be collectively referred to as the initialization components 112 (not shown herein for the sake of clarity).

As mentioned earlier, the computing device 100 may receive the update package 114 having the updated initialization components 116. The updated initialization components 116 may include an updated version of an initialization component. For instance, the updated initialization components 116 may include updated start-up instructions 206 (which may be an updated version of the start-up instructions 108), updated other sets of instructions 208 (which may be an updated version of the other sets of instructions 202), or both. The updated initialization components 116 may also include a common memory information set 210 that can be used for operationalization of the first RAM 102. Although not shown in FIG. 2, in an example, a component of the updated initialization components 116 may be same as the corresponding component of the initialization components 112. For instance, the other sets of instructions in the updated initialization components 116 may be identical to the other sets of instructions 202 in the second memory 106. The provision of components corresponding to each component of the initialization components 112, even if there is no update in a particular component, facilitates replacement of the whole of the initialization components 112 in the second memory 106 with the updated initialization components 116.

The updated initialization components 116 may be loaded into the second memory 106, as indicated by the arrow 212. The loading of the updated initialization components 116 may involve replacement of a component of the initialization components 112 with a corresponding component of the updated initialization components 116. For instance, the previous memory information set 110 may be replaced by the common memory information set 210. In an example, the replacement of a first component in the second memory 106 with a second component may involve overwriting the first component in the second memory 106 with the second component. The loading of the updated initialization components 116, according to various examples, is explained below.

In an example, to cause loading of the updated initialization components 116 into the second memory 106, the computing device 100 may first store the update package 114 in a storage 214 of the computing device 100 or in the first RAM 102. The storage 214 may be, for example, a hard-disk, solid-state drive (SSD), or the like. The update package 114 may be stored in a location in the storage 214 that is earmarked for storing update packages. In addition, an update flag may be set to indicate that an update is ready to be loaded into the second memory 106. In an example, the storage of the update package 114 in the earmarked location and the setting of the update flag may be performed in response to execution of an executable file (not shown in FIG. 2) by the processor 104. The executable file may be provided along with the update package 114. Upon storage of the update package 114 in the earmarked location, the computing device 100 may detect the presence of the updated initialization components 116 in the earmarked location based on the update flag during the next boot sequence, such as after restarting. Subsequently, the updated initialization components 116 may be retrieved from the earmarked location and loaded into the second memory 106. In an example, the detection and loading of the updated initialization components 116 may be performed by the processor 104 by executing the start-up instructions 108, which are loaded into the first RAM 102 from the second memory 106 during the boot sequence.

In another example, the loading of the updated initialization components 116 into the second memory 106 may happen during an operative state of the OS, i.e., after completion of the boot sequence. The loading may be performed by the processor 104 by executing loading instructions 216. The loading instructions 216 may be loaded, for example, into the first RAM 102 during the operative state of the OS. In an example, the loading instructions 216 may be received along with the update package 114.

The update package 114 may be common for different computing devices having different RAMs, such as different models of RAMs, installed thereon. For instance, the update package 114 may be used for applying updates to the computing device 100, which has the first RAM 102, and another computing device (not shown in FIG. 2) that has a different model of RAM than the first RAM 102. Accordingly, the common memory information set 210 may have information common for several RAMs and may be utilized for operationalizing several RAMs. However, owing to the differences between the different RAMs, for example, in terms of functionality, settings, and the like, the common memory information set 210 may not provide a complete operationalization of all RAMs it is applicable to. Instead, the common memory information set 210 may provide a basic level of operationalization of the applicable RAMs. For instance, a voltage rating specified in the common memory information set 210 may be the least among the voltage ratings of the different RAMs, so that no RAM is supplied with an excessive voltage. Further, a latency specified in the common memory information set 210 may be the highest among the latencies of the different RAMs.

To allow a complete operationalization of RAMs after the update, the update package 114 may include a memory information block 218 that has memory information sets corresponding to different RAMs. For instance, the memory information block 218 may include a first memory information set 226 corresponding to the first RAM 102, a second memory information set 228 corresponding to a second RAM (not shown in FIG. 2), and a third memory information set 230 corresponding to a third RAM (not shown in FIG. 2). The first memory information set 226 may be an updated version of the previous memory information set 110 or the same as the previous memory information set 110.

The computing device 100 may select the memory information set in the memory information block 218 that corresponds to the first RAM 102, i.e., the first memory information set 226. The selection may involve identification of the memory information set in the memory information block 218 that corresponds to the first RAM 102. To facilitate the identification, in an example, each memory information set in the memory information block 218 may have a corresponding identifier. The identifier may be an identifier of a RAM to which the memory information set corresponds or an identifier of a motherboard having the corresponding RAM. Accordingly, the computing device 100 may compare the identifiers associated with the memory information sets in the memory information block 218 with an identifier of the first RAM 102 or that of the motherboard of the computing device 100. An identifier of the motherboard may be utilized for identification because the identifier of the motherboard may depend on the RAM that is installed on the motherboard. The identifier may be referred to as an identifier corresponding to the first RAM 102. The identifier may be stored, for example, in the EC 204 or the memory controller 234, and may be accessed through a general purpose input/output (GPIO) pin of the EC 204 or the memory controller 234.

Based on the comparison, the computing device 100 may identify the first memory information set 226 as the one corresponding to the first RAM 102 and select the first memory information set 226. Subsequently, the first memory information set 226 may be loaded into the second memory 106, as indicated by the arrow 232. In an example, the instructions for the comparison, the selection, and the loading of the first memory information set 226 may be part of the start-up instructions 108. Further, the comparison, selection, and the loading may be performed by the processor 104 after loading the updated initialization components 116 into the second memory 106 and during the boot sequence, as explained earlier. In another example, the comparison, selection, and the loading may be performed by the processor 104 during the operative state of the OS by executing the loading instructions 216.

The first memory information set 226 may replace the common memory information set 210, which was loaded into the second memory 106 when the updated initialization components 116 was loaded into the second memory 106, in the second memory 106.

Upon loading the first memory information set 226 into the second memory 106, the first RAM 102 may be operationalized using the first memory information set 226. In an example, the operationalization may be performed after restarting the computing device 100. Further, the first memory information set 226 may be used for operationalization of the first RAM 102 during the subsequent initializations of the computing device 100. The operationalization of the first RAM 102 may be performed by a memory controller 234 or the processor 104. The memory controller 234 may be a digital circuit that manages the flow of data to and from the first RAM 102. In an example, the memory controller 234 may be implemented as part of a System on a Chip (SoC).

In some cases, it may not be possible to operationalize the first RAM 102 using the first memory information set 226. The failure to operationalize may be due to various reasons, such as an error in the first memory information set 226. To ensure operationalization of the first RAM 102 in such cases, the computing device 100 may utilize the previous memory information set 110 or the common memory information set 210. The computing device 100 may back up the previous memory information set 110, the common memory information set 210, or both in a third memory 236, as indicated by the arrows 238 and 240. The third memory 236 may be a non-volatile memory, such as a read-only memory (ROM) or a flash memory. In an example, the third memory 236 may be a secure memory that is inaccessible to software that may attempt to compromise firmware in the computing device 100. Accordingly, the third memory 236 may be referred to as a private memory or a private ROM (if the third memory 236 is a ROM). The backing-up of information sets in the third memory 236 prevents the information sets from being compromised. In an example, the third memory 236 may also store a copy of the start-up instructions loaded into the second memory 106, so that the copy may be loaded into the second memory 106 if the start-up instructions in the second memory 106 are compromised. The utilization of the previous memory information set 110 and the common memory information set 210 for ensuring operationalization of the first RAM 102 is explained below.

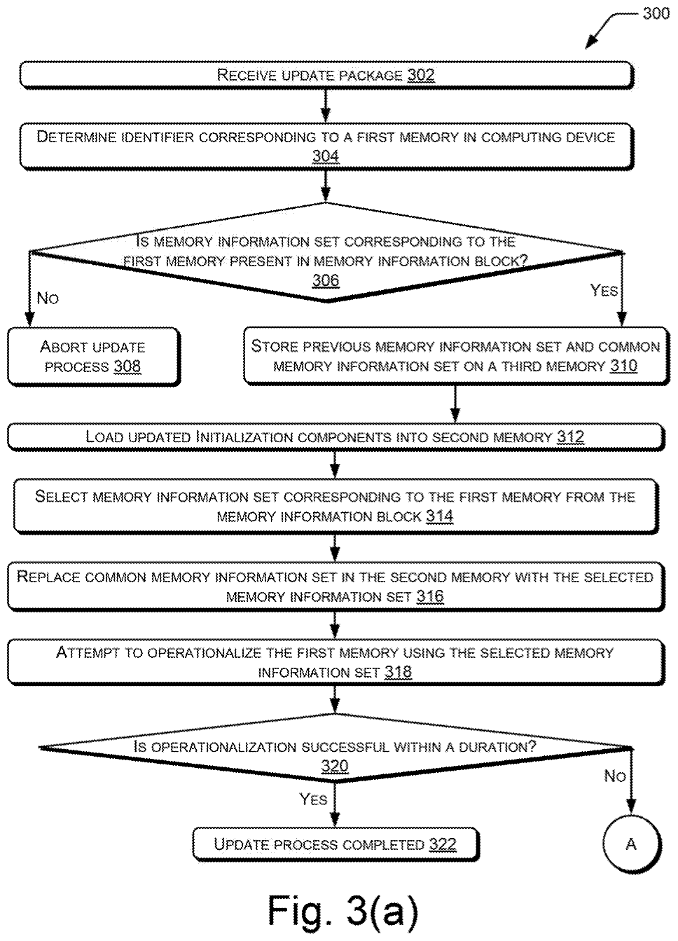

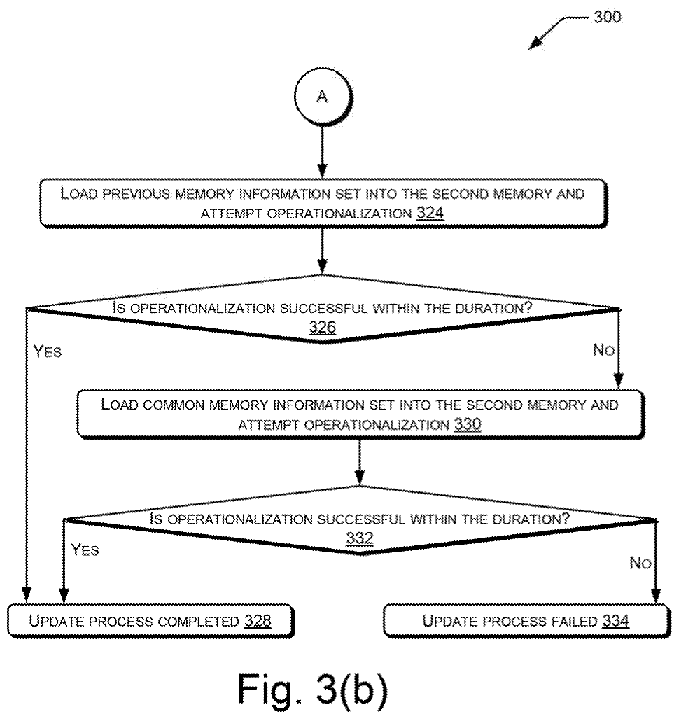

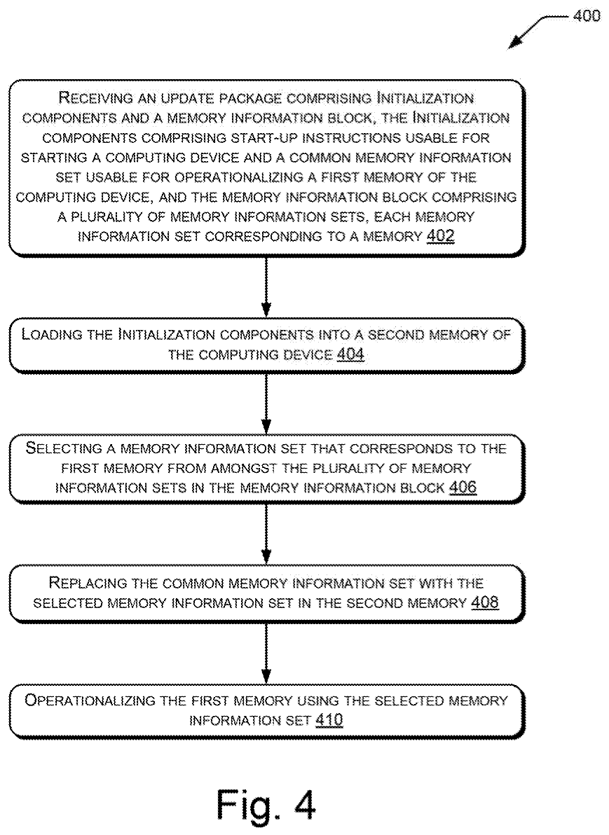

FIGS. 3(a) and 3(b) illustrate a computer-implemented method 300 for operationalization of the first RAM 102, according to an example implementation of the present subject matter. Further, FIG. 4 illustrates a computer-implemented method 400 for operationalizing a first memory is using a memory information set, according to an example implementation of the present subject matter.

The orders in which the methods 300 and 400 are described is not intended to be construed as a limitation, and any number of the described method blocks may be combined in any order to implement the methods 300 and 400, or alternative methods. Furthermore, the methods 300 and 400 may be implemented by processing resource(s) or computing device(s) through any suitable hardware, non-transitory machine-readable instructions, or a combination thereof.

It may be understood that blocks of the methods 300 and 400 may be performed by programmed computing devices and may be executed based on instructions stored in a non-transitory computer readable medium. The non-transitory computer readable medium may include, for example, digital memories, magnetic storage media, such as magnetic disks and magnetic tapes, hard drives, or optically readable digital data storage media. Further, although the methods 300 and 400 may be implemented in a variety of systems, the methods 300 and 400 are described in relation to the computing device 100, for ease of explanation. In an example, the blocks of the method 300 may be performed by the processor 104, the memory controller 234, or the embedded controller 204.

Referring to FIG. 3(a), at block 302, the update package 114 is received. The update package 114 may be received from a manufacturer of the computing device 100. At block 304, an identifier corresponding to the first RAM 102 is determined. The identifier may be the identifier of the first RAM 102 or that of the motherboard on which the first RAM 102 is installed, as explained above. At block 306, it may be determined if the memory information block 218 has a memory information set corresponding to the first RAM 102. For instance, it may be determined that the memory information block 218 has the first memory information set 226. The determination may be based on a comparison of the identifier determined at block 304 and the identifiers corresponding to the memory information sets in the memory information block 218, as explained earlier.

If a memory information set corresponding to the first RAM 102 is absent in the memory information block 218 (e.g., if the memory information block 218 does not have the first memory information set 226), at block 308, the update process may be aborted. Thus, the second memory 106 is prevented from being updated using an update package not applicable to the computing device 100. If a memory information set corresponding to the first RAM 102 is present in the memory information block 218, it may be determined that the update process may commence. Accordingly, at block 310, the previous memory information set 110 and the common memory information set 210 are stored on the third memory 236.

At block 312, the updated initialization components 116 may be loaded into the second memory 106. At block 314, the first memory information set 226 may be selected from the memory information block 218. In an example, the selection may be performed before block 310. For instance, upon the determination at block 306 that the memory information block 218 has the first memory information set 226 corresponding to the first RAM 102, the first memory information set 226 may be selected for being loaded into the second memory 106.

Further, at block 316, the common memory information set 210 may be replaced with the first memory information set 226 in the second memory 106. Since the updated initialization components 116 includes the common memory information set 210, the first RAM 102 may be operationalized using the common memory information set 210 in case of an interruption in the update process, such as an interruption that prevents replacement of the common memory information set 210 with the first memory information set 226.

At block 318, the computing device 100 may attempt to operationalize the first RAM 102 using the first memory information set 226 present in the second memory 106. In an example, the attempt to operationalize may be performed after restarting the computing device 100 using the updated contents in the second memory 106. At block 320, the computing device 100 may also determine if the operationalization of the first RAM 102 is successful. For instance, the computing device 100 may check if the operationalization of the first RAM 102 completes within a predetermined duration. The predetermined duration may be a duration within which the operationalization normally gets completed. For instance, if the operationalization normally gets completed within 10 milliseconds of booting of the computing device 100, the predetermined duration may be set at 15 milliseconds. If the operationalization completes within the predetermined duration, at block 322, it may be determined that the attempt to the operationalize has succeeded and that the update process is completed.

If the operationalization does not complete within the predetermined duration, the computing device 100 may determine that the attempt to operationalize has failed. In an example, the checking for completion of operationalization within the predetermined duration may be performed by the EC 204. The EC 204 may start a watchdog timer when the computing device 100 boots up for updating the second memory 106 and may check for arrival of a notification indicating that the operationalization is completed. The notification may be provided, for example, in response to execution of the start-up instructions 108. If the notification is not received within the predetermined duration, the EC 204 may infer that the operationalization using the first memory information set 226 is unsuccessful.

Referring to FIG. 3(b), at block 324, the first memory information set 226 may be replaced with the previous memory information set 110 in the second memory 106. The replacement may be performed, for example, by the EC 204 based on instructions that are part of the firmware of the EC 204. The EC 204 may perform the replacement after setting the computing device 100 to a low-power state, during which the processor 104 and the first RAM 102 are powered-off, but the EC 204, the second memory 106, and the third memory 236 are powered-on. The performance of the replacement during a powered-off state of the processor 104 ensures that the second memory 106 is not simultaneously accessed by the processor 104 and the EC 204, and therefore prevents corruption of the second memory 106.

Upon performing the replacement, the EC 204 may set the computing device 100 to a normal-power state, during which the processor 104 and the first RAM 102 are powered-on. Further, the computing device 100 may attempt to operationalize the first RAM 102 using the previous memory information set 110. At block 326, it may be determined if the operationalization completes within the predetermined duration. If the operationalization completes within the predetermined duration, at block 328, the update process is completed. Further, a notification may be provided that the operationalization of the first RAM 102 has been performed in a fail-safe mode and that customer service is to be contacted to resolve the issue.

If the operationalization does not complete within the predetermined duration, the computing device 100 may determine that the attempt to operationalize using the previous memory information set 110 has failed. Further, at block 330, the common memory information set 210 backed-up in the third memory 236 may be loaded into the second memory 106 by replacing the previous memory information set 110 with the common memory information set 210. The replacement may be performed, for example, by the EC 204 after setting the computing device 100 to the low-power state. Subsequently, the EC 204 may set the computing device 100 to the normal-power state. Further, at block 332, it may be determined if the operationalization is successful using the previous memory information set 110, such as within the predetermined duration. If successful, at block 328, the update process is completed. Further, a notification may be provided that the operationalization of the first RAM 102 has been performed in a fail-safe mode and that customer service is to be contacted to resolve the issue. If unsuccessful, at block 334, it is determined that the update process has failed, and an error indicating that no memory is found and that the boot process has failed may be provided on a display (not shown in FIG. 3(b)) of the computing device 100. Further, a buzzer (not shown in FIG. 3(b)) of the computing device 100 may beep and a light emitting diode (LED) (not shown in FIG. 3(b)) of the computing device 100 may blink to indicate the error.

Although the replacement of the memory information sets is explained as being performed by the EC 204, in other examples, other controllers that operate under the low-power state of the computing device 100 may be utilized for the replacement. For instance, the replacement may be performed by a Super Input/Output (Super I/O). The Super I/O may be provided instead of or in addition to the EC 204 in the computing device 100. Further, the Super I/O may perform other functions that are explained as being performed by the EC 204, such as checking for successful operationalization of the first RAM 102.

The backing up of the memory information sets in the third memory 236 and attempting to operationalize the first RAM 102 using the backed-up memory information sets ensures that the first RAM 102 can be operationalized even if the first memory information set 226 is faulty. Thus, the present subject matter provides a fail-safe update process.

FIG. 4 illustrates a computer-implemented method 400 for operationalizing a first memory is using a memory information set, according to an example implementation of the present subject matter. In an example, the blocks of the method 400 may be performed by a processing resource, such as the processor 104, the memory controller 234, or the EC 204.

At block 402, an update package may be received. The update package may include initialization components and a memory information block. The initialization components may include start-up instructions usable for starting the computing device and a common memory information set usable for operationalizing a first memory of the computing device. The memory information block may include a plurality of memory information sets, where each memory information set corresponds to a memory.

In an example, the computing device may be the computing device 100 and the first memory may be the first memory 102. The update package may be, for example, the update package 114. Accordingly, the initialization components may be the updated initialization components 116, the start-up instructions may be the updated start-up instructions 206, the common memory information set may be the common memory information set 210, and the memory information block may be the memory information block 218. In an example, the start-up instructions may be Basic Input/Output System (BIOS), Unified Extensible Firmware Interface (UEFI), or both.

At block 404, the initialization components may be loaded into a second memory of the computing device. The second memory may be the second memory 106. In an example, the loading of the initialization components may be performed during a booting process of the computing device upon detecting the initialization components in a location on a storage device earmarked for storing updated initialization components, as explained with reference to FIG. 2. In another example, the loading may be performed during an operative state of an operating system of the computing device.

At block 406, a memory information set that corresponds to the first memory may be selected from amongst the plurality of memory information sets in the memory information block. The selected memory information set may be, for example, the first memory information set 226. In an example, selecting the memory information set corresponding to the first memory includes comparing an identifier corresponding to the first memory with a plurality of identifiers in the memory information block, where each identifier in the memory information block corresponds to a memory information set in the memory information block. The identifier corresponding to the first memory may be an identifier of the first memory or an identifier of a motherboard on which the first memory is installed, as explained earlier.

At block 408, the common memory information set in the second memory is replaced with the selected memory information set, as explained with reference to FIG. 2. Further, at block 410, the first memory is operationalized using the selected memory information set. In an example, the operationalizing may be performed by a memory controller of the computing device, such as the memory controller 234.

In an example, the method 400 may include storing the common memory information set in a third memory, such as the third memory 236. Further, it may be determined whether operationalization of the first memory using the selected memory information set is completed within a predetermined duration. In response to non-completion of the operationalization within the predetermined duration, the common memory information set may be loaded into the second memory. Further, the first memory may be operationalized using the common memory information set. Prior to attempting to operationalize the first memory using the common memory information set, in an example, a previous memory information set, such as the previous memory information set 110, which was previously loaded into the second memory, may be utilized for operationalizing the first memory, as explained with reference to FIG. 3(b).

In an example, prior to loading the initialization components into the second memory, the method 400 may include determining if the memory information block includes a memory information set corresponding to the first memory. The loading of the initialization components into the second memory may be performed if the memory information set corresponding to the first memory is present in the memory information block. If the memory information set corresponding to the first memory is absent in the memory information block, it may be determined that the initialization components is not to be loaded into the second memory. That is, the update process may be aborted, as explained with reference to FIG. 3(a).

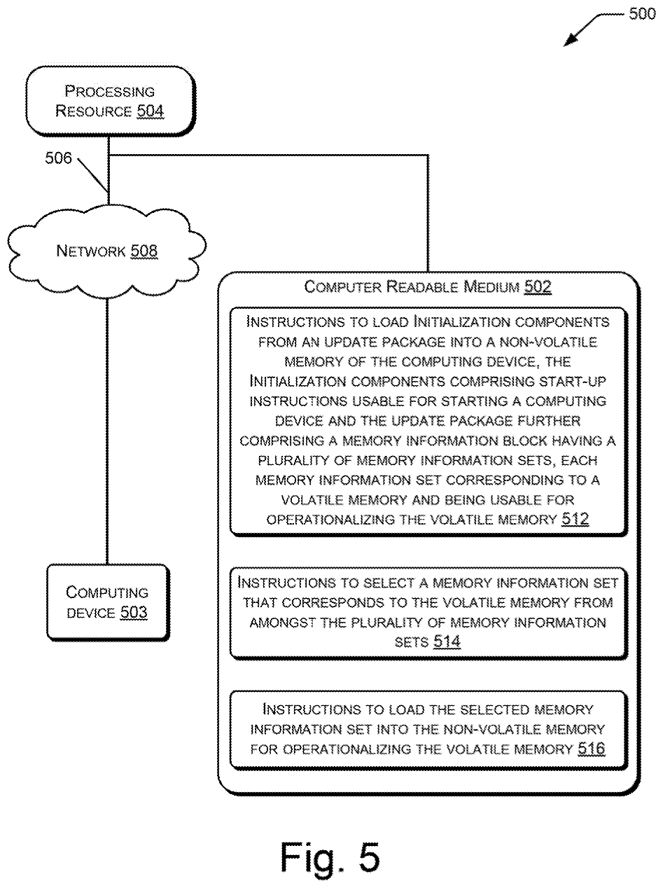

FIG. 5 illustrates a computing environment 500 implementing a non-transitory computer-readable medium 502 for operationalizing a volatile memory of a computing device using a memory information set, according to an example implementation of the present subject matter. In an example, the non-transitory computer-readable medium 502 may be utilized by a computing device 503, which may be, for example, the computing device 100. In an example, the computing environment 500 may include a processing resource 504 communicatively coupled to the non-transitory computer-readable medium 502 through a communication link 506. The processing resource 504 may be, for example, the processor 104, the embedded controller 204, the memory controller 234, or any combination thereof.

The non-transitory computer-readable medium 502 may be an internal memory device or an external memory device. The non-transitory computer-readable medium 502 may be implemented in the computing device 503. In an example, the communication link 506 may be a direct communication link, such as any memory read/write interface. In another example, the communication link 506 may be an indirect communication link, such as a network interface. In such a case, the processing resource 504 may access the non-transitory computer-readable medium 502 through a network 508. The network 508 may be a single network or a combination of multiple networks and may use a variety of different communication protocols.

In an example implementation, the non-transitory computer-readable medium 502 includes a set of computer-readable instructions for selection of a memory information set for operationalizing a volatile memory of the computing device. The volatile memory may be, for example, the first memory 102. The set of computer-readable instructions can be accessed by the processing resource 504 through the communication link 506 and subsequently executed.

Referring to FIG. 5, in an example, the non-transitory computer-readable medium 502 includes instructions 512 that cause the processing resource 504 to load initialization components from an update package into a non-volatile memory of the computing device 503. The initialization components include start-up instructions usable for starting the computing device 503. Further, the update package may include a memory information block having a plurality of memory information sets. Each memory information set corresponds to a volatile memory and is usable for operationalizing the volatile memory. The update package may be, for example, the update package 114. Accordingly, the initialization components may be the updated initialization components 116, the start-up instructions may be the updated start-up instructions 206, and the memory information block may be the memory information block 218.

The non-transitory computer-readable medium 502 includes instructions 514 that cause the processing resource 504 to select a memory information set that corresponds to the volatile memory from amongst the plurality of memory information sets. The selection may be based on an identifier associated with each memory information set in the memory information block and an identifier corresponding to the volatile memory, as explained with reference to FIG. 2.

The non-transitory computer-readable medium 502 includes instructions 516 that cause the processing resource 504 to load the selected memory information set into the non-volatile memory for operationalizing the volatile memory. In an example, the non-transitory computer-readable medium 502 includes instructions executable to restart the computing device 503 in response to loading of the selected memory information set, and to operationalize the volatile memory using the selected memory information set stored in the non-volatile memory upon the restarting. In an example, the operationalization may be performed by a memory controller of the computing device, such as the memory controller 234.

In an example, the initialization components include a common memory information set, such as the common memory information set 210, having information common to a plurality of volatile memories. Accordingly, to load the selected memory information set into the non-volatile memory, the instructions executable to replace the common memory information set with the selected memory information set in the non-volatile memory.

In an example, in response to non-completion of the operationalization of the volatile memory within a predetermined duration, the instructions are executable to operationalize the volatile memory using the common memory information set or a previous memory information set. The previous memory information set is a memory information set that was previously stored in the non-volatile memory prior to loading of the initialization components into the non-volatile memory. The previous memory information set may be, for example, the previous memory information set 110.

The provision of a memory information block having a plurality of memory information sets and the selection of a memory information set corresponding to the memory in a computing device ensures that the plurality of memory information sets is not to be stored in the computing device. Therefore, adequate space may be made available for storing the instructions usable for starting up of the computing device.

The present subject matter provides a fail-safe update process by backing up various memory information sets and utilizing them in case of failure to operationalize with a selected memory information set. Further, the provision of the common memory information set in the update package allows booting the computing device even in case of an interruption in the update process.

Since not all memory information sets in the memory information block are to be stored in the second memory, the memory information block may have several memory information sets corresponding to several memories, without having regard to the space available in the second memory. Thus, the update package may be utilized to update memory information sets corresponding to several memories. Further, the models of memories that can be supported by computing devices may be increased, thereby providing greater flexibility in terms of the model of memory that can be installed in a computing device. Also, the process of rolling out update packages is also simplified, as a single update package may be applicable to several memories.

The present subject matter also prevents the use of a dedicated memory to store memory information sets, thereby achieving cost and space savings. The present subject matter can be utilized in scenarios where motherboards are to be made compact. For instance, the present subject matter can be utilized in motherboards implementing a memory down technique, according to which memories are directly soldered onto the motherboard, without utilizing slots and connectors, for space saving.

Although examples and implementations of present subject matter have been described in language specific to structural features and/or methods, it is to be understood that the present subject matter is not necessarily limited to the specific features or methods described. Rather, the specific features and methods are disclosed and explained in the context of a few example implementations of the present subject matter.

What is claimed is:

1. A computing device comprising:
a first memory;
a second memory to store initialization components, the initialization components comprising instructions for starting up the computing device and a memory information set usable for operationalizing the first memory; and
a processor to:
load updated initialization components from an update package into the second memory;
select a memory information set that corresponds to the first memory from amongst a plurality of memory information sets in the update package, wherein each of the plurality of memory information sets corresponds to a memory; and
load the selected memory information set into the second memory to operationalize the first memory.

2. The computing device of claim 1, further comprising a memory controller to operationalize the first memory using the selected memory information set, subsequent to loading the selected memory information set into the second memory.

3. The computing device of claim 1, wherein, prior to loading of the updated initialization components into the second memory, the second memory has a previous memory information set stored thereon to operationalize the first memory, wherein the updated initialization components comprise a common memory information set having information common to a plurality of memories, and wherein the processor is to:
store the previous memory information set on a third memory of the computing device; and
store the common memory information set on the third memory, wherein the processor is further to:
replace the previous memory information set on the second memory with the common memory information set to load the updated initialization components into the second memory; and
replace the common memory information set on the second memory with the selected memory information set to load the selected memory information set into the second memory.

4. The computing device of claim 3, further comprising a controller, wherein, upon loading the selected memory information set into the second memory, the controller is to:
determine if operationalization of the first memory using the selected memory information set is successful;
in response to a failed operationalization of the first memory, replace the selected memory information set with the previous memory information set in the second memory, for operationalization of the first memory using the previous memory information set;
determine if operationalization of the first memory using the previous memory information set is successful; and
in response to a failure to operationalize the first memory using the previous memory information set, replace, in the second memory, the previous memory information set with the common memory information set, for operationalization of the first memory using the common memory information set.

5. The computing device of claim 1, further comprising a storage, wherein, to load updated initialization components from the update package into the second memory, the processor is to:
store the update package in a location in the storage that is earmarked for storing update packages;
set an update flag to indicate that an update is ready to be loaded into the second memory;
detect presence of the updated initialization components in the earmarked location based on the update flag during a subsequent boot sequence of the computing device; and
retrieve the updated initialization components from the earmarked location for loading into the second memory.

6. The computing device of claim 1, wherein the first memory is a random access memory (RAM), and wherein the second memory is a non-volatile memory that is to be accessed by the processor during starting-up of the computing device.

7. A computer-implemented method comprising:
receiving an update package comprising initialization components and a memory information block, the initialization components comprising start-up instructions usable for starting a computing device and a common memory information set usable for operationalizing a first memory of the computing device, and the memory information block comprising a plurality of memory information sets, each memory information set corresponding to a memory;
loading the initialization components into a second memory of the computing device;
selecting a memory information set that corresponds to the first memory from amongst the plurality of memory information sets in the memory information block;
replacing the common memory information set with the selected memory information set in the second memory; and
operationalizing the first memory using the selected memory information set.

8. The method of claim 7, further comprising:
storing the common memory information set in a third memory of the computing device;
determining whether operationalization of the first memory using the selected memory information set is completed within a predetermined duration;
in response to non-completion of the operationalization within the predetermined duration,
loading the common memory information set into the second memory; and
operationalizing the first memory using the common memory information set.

9. The method of claim 7, wherein, prior to loading the initialization components into the second memory, the method comprises:
determining if the memory information block comprises a memory information set corresponding to the first memory;
loading the initialization components into the second memory in response to the presence of the memory information set corresponding to the first memory in the memory information block; and
determining that loading of the initialization components into the second memory is not to be performed in response to the absence of the memory information set corresponding to the first memory in the memory information block.

10. The method of claim 7, wherein selecting the memory information set corresponding to the first memory comprises comparing an identifier corresponding to the first memory with a plurality of identifiers in the memory information block, wherein each identifier in the memory information block corresponds to a memory information set in the memory information block.

11. The method of claim 7, wherein the start-up instructions comprise instructions for Basic Input/Output System (BIOS) or Unified Extensible Firmware Interface (UEFI).

12. A non-transitory computer-readable medium comprising instructions for selection of a memory information set for operationalizing a volatile memory of a computing device, the instructions being executable by a processing resource to:
load initialization components from an update package into a non-volatile memory of the computing device, the initialization components comprising start-up instructions usable for starting a computing device and the update package further comprising a memory information block having a plurality of memory information sets, each memory information set corresponding to a volatile memory and being usable for operationalizing the volatile memory;
select a memory information set that corresponds to the volatile memory from amongst the plurality of memory information sets; and
load the selected memory information set into the non-volatile memory for operationalizing the volatile memory.

13. The computer-readable medium of claim 12, further comprising instructions executable by the processing resource to:
restart the computing device in response to loading the selected memory information set; and
operationalize the volatile memory using the selected memory information set stored in the non-volatile memory upon the restarting.

14. The computer-readable medium of claim 12, wherein the initialization components comprise a common memory information set having information common to a plurality of volatile memories, wherein, to load the selected memory information set into the non-volatile memory, the instructions are executable by the processing resource to:
replace the common memory information set with the selected memory information set in the non-volatile memory.

15. The computer-readable medium of claim 14, further comprising instructions executable by the processing resource to:
operationalize the volatile memory using the selected memory information set stored in the non-volatile memory; and
in response to non-completion of the operationalization of the volatile memory within a predetermined duration, operationalize the volatile memory using the common memory information set or a previous memory information set, wherein the previous memory information set is a memory information set that was previously stored in the non-volatile memory prior to loading of the initialization components into the non-volatile memory.
